(19) United States
(12) Patent Application Publication
(10) Pub. No.: US 2026/0040943 A1
(43) Pub. Date: Feb. 5, 2026

(54) OPTICAL ENGINE DEVICE AND SEMICONDUCTOR PACKAGE INCLUDING THE SAME

(71) Applicant: SAMSUNG ELECTRONICS CO., LTD., Suwon-si (KR)

(72) Inventors: Jing Cheng LIN, Suwon-si (KR); Jung Hua CHANG, Suwon-si (KR)

(21) Appl. No.: 19/098,663

(22) Filed: Apr. 2, 2025

(30) Foreign Application Priority Data
Jul. 31, 2024 (KR) 10-2024-0102049

(51) Int. Cl. H01L 23/36; G02B 6/42; H01L 23/00; H01L 23/31; H01L 23/48; H01L 23/538; H01L 25/16

(52) U.S. Cl. CPC H01L 23/36; G02B 6/4214; H01L 23/3135; H01L 23/481; H01L 24/08; H01L 25/167; H01L 23/5385; H01L 2224/08145

(57) ABSTRACT

An optical engine device includes an electronic integrated circuit (EIC) chip, and a photonic chip on the EIC chip, where the PIC chip includes a first photonic chip sidewall, a photonic chip substrate having an inclined upper surface, and a reflective pattern on the inclined upper surface of the photonic chip substrate, and where at least a portion of the reflective pattern is horizontally spaced apart from the first photonic chip sidewall.

### CROSS-REFERENCE TO RELATED APPLICATION

This application is based on and claims priority under 35 U.S.C. § 119 to Korean Patent Application No. 10-2024-0102049, filed on Jul. 31, 2024, in the Korean Intellectual Property Office, the disclosure of which is incorporated by reference herein in its entirety.

### BACKGROUND

The present disclosure relates to a semiconductor package, and more particularly, to an optical engine device and a semiconductor package including the same.

A semiconductor package may include an integrated circuit chip implemented in a form suitable for use in electronic products. Typically, in semiconductor packages, semiconductor chips are mounted on a printed circuit board and electrically connected thereto using bonding wires or bumps. With the development of the electronics industry, various research is being conducted to improve the performance of semiconductor packages.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an optical engine device which may have improved thermal properties and improved performance, and a semiconductor package including the same.

Further, one or more example embodiments provide a miniaturized optical engine device.

According to an aspect of an example embodiment, an optical engine device may include an electronic integrated circuit (EIC) chip, and a photonic chip on the EIC chip, where the photonic chip includes a first photonic chip sidewall, a photonic chip substrate having an inclined upper surface, and a reflective pattern on the inclined upper surface of the photonic chip substrate, and where at least a portion of the reflective pattern is horizontally spaced apart from the first photonic chip sidewall.

According to an aspect of an example embodiment, a semiconductor package may include an interposer substrate, a semiconductor chip on an upper surface of the interposer substrate, a memory device on the upper surface of the interposer substrate and horizontally spaced apart from the semiconductor chip, and an optical engine device on the upper surface of the interposer substrate, where the optical engine device includes an EIC chip including a through via, a photonic chip on the EIC chip and including a first photonic chip sidewall, and a fiber optic device on the first photonic chip sidewall, where the photonic chip further includes a reflective pattern horizontally spaced apart from at least a portion of the fiber optic device, and the first photonic chip sidewall is vertically aligned with a first EIC sidewall of the EIC chip and a first interposer sidewall of the interposer substrate.

According to an aspect of an example embodiment, an optical engine device may include a redistribution substrate including a lower insulating layer and a redistribution pattern, conductive bumps on a lower surface of the redistribution substrate, an EIC chip on an upper surface of the redistribution structure, and a photonic chip on the EIC chip, where the EIC chip includes an EIC substrate, a through via in the EIC substrate, a lower wiring layer on a lower surface of the EIC substrate, the lower wiring layer including a lower insulating layer and a lower conductive wire, and an upper wiring layer on an upper surface of the EIC substrate, the upper wiring layer including an upper insulating layer and an upper conductive wire, and where the photonic chip includes a first photonic chip sidewall, a photonic chip substrate having an inclined upper surface, insulating layers on a lower surface of the photonic chip substrate, a bonding coupler between the insulating layers, a metal block pattern vertically spaced apart from a lower surface of the bonding coupler, and a reflective pattern on the inclined upper surface of the photonic chip substrate and horizontally spaced apart from the first photonic chip sidewall.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1A is a cross-sectional view of an optical engine device according to one or more embodiments;

FIG. 1B is an enlarged view of region I of FIG. 1A according to one or more embodiments;

FIG. 1C is an enlarged view of region II of FIG. 1A according to one or more embodiments;

FIG. 2A is a cross-sectional view of an optical engine device according to one or more embodiments;

FIG. 2B is a cross-sectional view of an optical engine device according to one or more embodiments;

FIG. 2C is a cross-sectional view of an optical engine device according to one or more embodiments;

FIG. 2D is a cross-sectional view of an optical engine device according to one or more embodiments;

FIG. 3A is a cross-sectional view of a semiconductor package according to one or more embodiments;

FIG. 3B is a cross-sectional view of a semiconductor package according to one or more embodiments;

FIG. 3C is a cross-sectional view of a semiconductor package according to one or more embodiments;

FIGS. 4A to 4L are diagrams illustrating a method of manufacturing an optical engine device and a semiconductor package including the same, according to one or more embodiments; and

FIG. 5 is a cross-sectional view of an optical engine device, according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

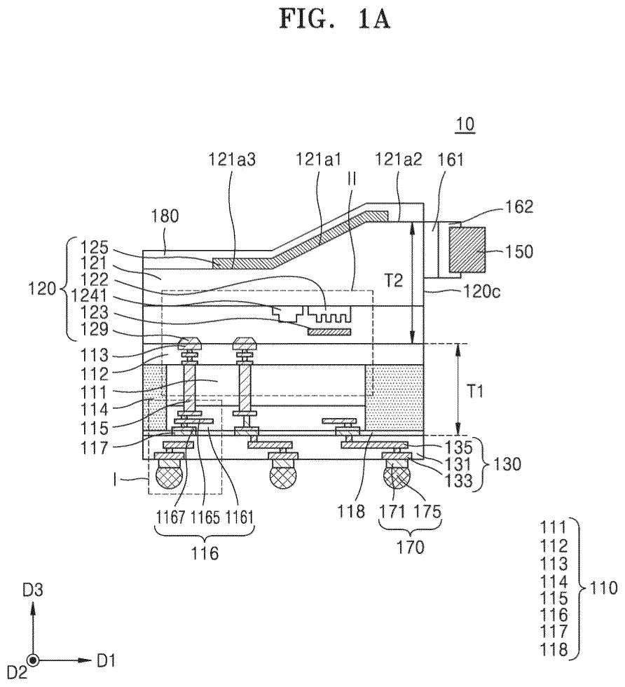

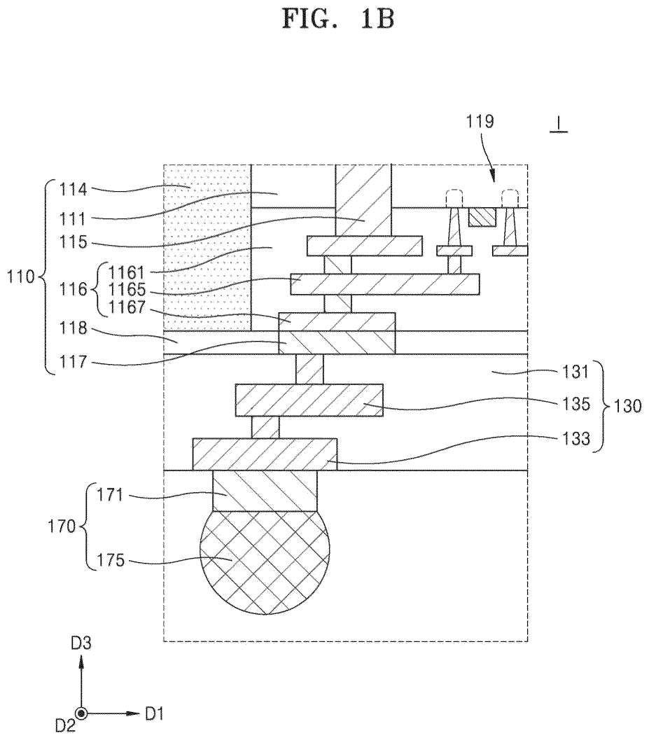

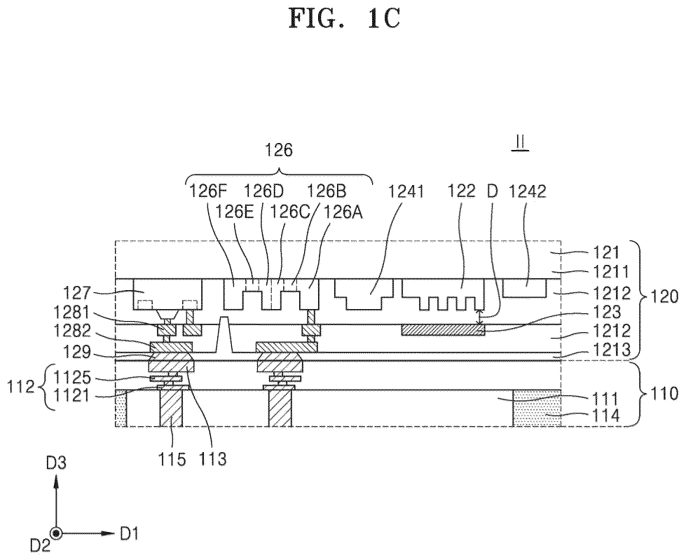

FIG. 1A is a cross-sectional view of an optical engine device according to one or more embodiments. FIG. 1B is an enlarged view of region I of FIG. 1A according to one or more embodiments. FIG. 1C is an enlarged view of region II of FIG. 1A according to one or more embodiments.

Referring to FIGS. 1A to 1C, a semiconductor package may include an optical package, and the optical package may include an optical engine device 10. The optical engine device 10 may include a redistribution substrate 130, an electronic integrated circuit (EIC) chip 110, a photonic chip 120, conductive bumps 170, a fiber optic device 150, and a protective layer 180.

The redistribution substrate 130 may include a substrate insulating layer 131 and redistribution patterns 135. The substrate insulating layer 131 may include a photo-imageable dielectric (PID) material. The PID material may include a polymer. The PID material may include at least one of, for example, a photosensitive polyimide, a polybenzoxazole, a phenol-based polymer, and a benzocyclobutene-based polymer. The substrate insulating layer 131 may include a plurality of stacked layers. The layers of the substrate insulating layer 131 may include the same material. The interface between adjacent layers of the substrate insulating layer 131 may not be distinguished. The number of layers of the substrate insulating layer 131 may vary.

The redistribution patterns 135 may be provided in the substrate insulating layer 131. For example, the redistribution patterns 135 may be provided between layers of the substrate insulating layer 131. The redistribution patterns 135 may pass through at least one of the layers of the substrate insulating layer 131. Being electrically connected to the redistribution substrate 130 may refer to being electrically connected to at least one of the redistribution patterns 135. The redistribution patterns 135 may include a conductive material, such as copper (Cu).

The redistribution substrate 130 may further include seed patterns. The seed patterns may be provided on the redistribution patterns 135. For example, the seed patterns may cover upper surfaces of the redistribution patterns 135. The seed patterns may include a different metal from the redistribution patterns 135. For example, the seed patterns may include a conductive seed material. The conductive seed material may include titanium (Ti), Ti—Cu, or alloys thereof. The redistribution patterns 135 may be formed by an electroplating process using seed patterns as an electrode.

The redistribution substrate 130 may further include redistribution pads 133. The redistribution pads 133 may be provided on a lower surface of the redistribution substrate 130 and may be electrically connected to the redistribution patterns 135. For example, the redistribution pads 133 may be provided on a lower surface of the substrate insulating layer 131. The redistribution pads 133 may include a metal, such as Cu.

The optical engine device 10 may further include the conductive bumps 170. Each of the conductive bumps 170 may include a pillar pattern 171 and a solder pattern 175. The solder pattern 175 may be formed using a solder ball. The solder pattern 175 may include a solder material. The solder material may include for example, tin (Sn), bismuth (Bi), lead (Pb), silver (Ag), or alloys thereof. The pillar pattern 171 may be positioned between the solder pattern 175 and the corresponding redistribution pad 133 and may be electrically connected to the solder pattern 175 and the corresponding redistribution pad 133. The pillar pattern 171 may include a different metal from the solder pattern 175. For example, the pillar pattern 171 may include Cu or a Cu alloy. Each of the conductive bumps 170 may not include the pillar pattern 171. In this case, the solder pattern 175 may be disposed directly on a lower surface of the corresponding one of the redistribution pads 133.

The EIC chip 110 may be provided on the redistribution substrate 130. A width of the EIC chip 110 may be substantially the same as a width of the redistribution substrate 130 (e.g., may be the same as within a permitted error range or by other acceptable range standards).

The EIC chip 110 may include a first substrate 111 (hereinafter referred to as an EIC substrate), through vias 115, a lower wiring layer 116, first lower pads 117, an upper wiring layer 112, and first upper pads 113. The first substrate 111 may include a semiconductor substrate. The through vias 115 may pass through the first substrate 111. For example, the through vias 115 may pass through an upper surface or a lower surface of the first substrate 111. The through vias 115 may include a metal material, such as Cu or tungsten (W). The EIC chip 110 may include the through vias 115 and have a relatively small thickness T1. The thickness T1 of the EIC chip 110 may be from about 50 μm to about 100 μm. Accordingly, the optical engine device 10 may be reduced in thickness and miniaturized.

A first direction D1 may be parallel to the lower surface of the first substrate 111. A second direction D2 may be parallel to the lower surface of the first substrate 111 and may be substantially perpendicular to the first direction D1. A third direction D3 may be substantially perpendicular to the lower surface of the first substrate 111. The third direction D3 may include a vertical direction.

The lower wiring layer 116 may be provided on the lower surface of the first substrate 111. As shown in FIG. 1B, the lower wiring layer 116 may include a lower insulating layer 1161 and lower conductive wires 1165. The lower insulating layer 1161 may include a silicon-containing insulating material. The silicon-containing insulating material may include silicon oxide, silicon nitride, silicon oxynitride, silicon carbonitride, tetraethyl orthosilicate (TEOS), and/or combinations thereof. The lower insulating layer 1161 may include a plurality of stacked layers.

The lower conductive wires 1165 may be provided in the lower insulating layer 1161. For example, the lower conductive wires 1165 may be provided between the layers of the lower insulating layer 1161. The conductive wires 1165 may be electrically connected to the through vias 115. The lower conductive wires 1165 may include a conductive material, such as a metal. For example, the lower conductive wires 1165 may include Cu, W, aluminum (Al), Ti, tantalum (Ta), and/or combinations thereof.

The lower wiring layer 116 may further include bonding pads 1167. The bonding pads 1167 may be provided on a lower surface of the lower insulating layer 1161. The bonding pads 1167 may be electrically connected to the first through vias 115 or integrated circuits 119 through the lower conductive wires 1165. The bonding pads 1167 may include a conductive material, such as Cu.

The EIC chip 110 may further include the integrated circuits 119, as shown in FIG. 1B. The integrated circuits 119 may be provided on the lower surface of the first substrate 111. The integrated circuits 119 may be electrically connected to the through vias 115 or the first lower pads 117 through the lower conductive wires 1165. The integrated circuits 119 may include, for example, transistors.

The first lower pads 117 may be provided on a lower surface of the EIC chip 110. For example, the first lower pads 117 may be respectively provided on lower surfaces of the bonding pads 1167. The first lower pads 117 may be electrically connected to the conductive bumps 170 through the redistribution patterns 135. Since the redistribution patterns 135 are provided, at least one conductive bump 170 may not be vertically aligned with the first lower pad 117 electrically connected thereto. The first lower pads 117 may include a metal. For example, the first lower pads 117 may include Cu, W, Al, Ti, Ta, and/or combinations thereof.

The bonding pads 1167 may be bonded directly to the first lower pads 117. The direct bonding may include hybrid bonding. Hereinafter, for simplicity of explanation, a single bonding pad 1167 and a single first lower pad 117 may be described. During the direct bonding process, the metal in the first lower pad 117 may be diffused into the bonding pad 1167 and the metal in the bonding pad 1167 may be diffused into the first lower pad 117. Thus, the first lower pad 117 may be rigidly bonded to the bonding pad 1167. The interface between the bonding pad 1167 and the first lower pad 117 may not be distinguished. In FIGS. 1A and 1B, the interface between the bonding pad 1167 and the first lower pad 117 may include a virtual interface. The bonding pad 1167 may include the same metal as the first lower pad 117. A sidewall of the bonding pad 1167 may not be vertically aligned with a sidewall of the first lower pad 117.

The EIC chip 110 may further include a lower insulating pattern 118. The lower insulating pattern 118 may be provided between the lower wiring layer 116 and the redistribution substrate 130. The lower insulating pattern 118 may cover sidewalls of the first lower pads 117. The lower insulating pattern 118 may include a silicon-containing insulating material.

The lower insulating layer 1161 may directly contact the lower insulating pattern 118 and may be connected thereto by direct bonding. For example, a chemical bond may be provided between the lower insulating layer 1161 and the lower insulating pattern 118. The chemical bond may include a covalent bond. The lower insulating layer 1161 may include the same insulating material as the lower insulating pattern 118. The interface between the lower insulating layer 1161 and the lower insulating pattern 118 may not be distinguished. In FIGS. 1A and 1B, the interface between the lower insulating pattern 118 and the lower insulating layer 1161 may include a virtual interface.

As shown in FIG. 1A, the optical engine device 10 may further include a sealing layer 114. The sealing layer 114 may be provided between the redistribution substrate 130 and the upper wiring layer 112. For example, the sealing layer 114 may be provided between the lower insulating pattern 118 and the upper wiring layer 112 and may cover a sidewall of the lower wiring layer 116 and a sidewall of the first substrate 111. The lower insulating pattern 118 may extend between the sealing layer 114 and the redistribution substrate 130. Sidewalls of the sealing layer 114 may be vertically aligned with sidewalls of the lower insulating pattern 118, sidewalls of the redistribution substrate 130, and sidewalls of the upper wiring layer 112. The sealing layer 114 may include a silicon-containing insulating material. For example, the sealing layer 114 may include, but is not limited to, silicon oxide.

The upper wiring layer 112 may be provided on an upper surface of the first substrate 111 and an upper surface of the sealing layer 114. As shown in FIG. 1C, the upper wiring layer 112 may include an upper insulating layer 1121 and upper conductive wires 1125. The upper insulating layer 1121 may cover the upper surface of the first substrate 111 and the upper surface of the sealing layer 114. The upper insulating layer 1121 may include a silicon-containing insulating material or a PID material. The upper insulating layer 1121 may include a multilayer but is not limited thereto.

The upper conductive wires 1125 may be provided in the upper insulating layer 1121 and on the first substrate 111. The upper conductive wires 1125 may be electrically connected to the through vias 115. Being electrically connected to the upper wiring layer 112 may include being electrically connected to the upper conductive wires 1125. The upper conductive wires 1125 may include a metal material, such as Cu. As an example, the upper conductive wires 1125 may include upper redistribution patterns. In this case, the upper wiring layer 112 may further include upper seed patterns. The upper seed patterns may be provided on the lower surfaces of the upper conductive wires 1125. The top seed patterns may include a conductive seed material.

The first upper pads 113 may be exposed on an upper surface of the EIC chip 110. The first upper pads 113 may be provided on the upper surface of the upper wiring layer 112. For example, the first upper pads 113 may be provided on the upper insulating layer 1121. The upper insulating layer 1121 may cover sidewalls and lower surfaces of the first upper pads 113. The first upper pads 113 may be electrically connected to the through vias 115 through the upper conductive wires 1125. The first upper pads 113 may include a metal material, such as Cu. The upper surface of the EIC chip 110 may include upper surfaces of the first upper pads 113 and an upper surface of the upper insulating layer 1121.

The photonic chip 120 may be disposed on the EIC chip 110. The photonic chip 120 may include a photonic integrated circuit (PIC) chip. The photonic chip 120 may be provided on the upper surface of the upper insulating layer 1121 and the upper surface of the sealing layer 114.

The photonic chip 120 may include a second substrate 121 (hereinafter referred to as a photonic substrate), second lower pads 129, a grating coupler 122, a metal block pattern 123, and a reflective pattern 125. The second substrate 121 may include a silicon substrate or a silicon on insulator (SOI) substrate. The second substrate 121 may be transparent and transmit light.

Referring to FIG. 1C, the grating coupler 122 may be provided on a lower surface of the second substrate 121. The grating coupler 122 may be formed by patterning a portion of the second substrate 121. The metal block pattern 123 may be provided relative to a lower surface of the grating coupler 122 and may be vertically spaced apart from the lower surface of the grating coupler 122. The distance D between the metal block pattern 123 and the grating coupler 122 may be from about 0.5 μm to about 5 μm. Since the distance D between the metal block pattern 123 and the grating coupler 122 satisfies the above conditions, the photonic chip 120 may have excellent optical properties. The metal block pattern 123 may have a relatively high reflectivity. For example, the metal block pattern 123 may have a reflectivity of 70% or greater for light having a wavelength of 0.6 μm or greater. For example, the metal block pattern 123 may have a reflectivity of about 70% to about 100% for light having a wavelength of 0.6 μm or greater. The metal block pattern 123 may include Ag, gold (Au), Cu, Al, and/or alloys thereof. The light passing through the grating coupler 122 may be reflected by the metal block pattern 123. The thickness of the metal block pattern 123 may be 100 nm or greater.

The photonic chip 120 may further include a first waveguide 1241. The first waveguide 1241 may be provided on the lower surface of the second substrate 121 and may be arranged laterally to the grating coupler 122. As an example, the first waveguide 1241 may include, but is not limited to, a rib waveguide. The first waveguide 1241 may be formed by patterning a portion of the second substrate 121. Lateral spacing may refer to components being spaced apart laterally across horizontal directions, such as direction D1 and direction D2.

The photonic chip 120 may further include a second waveguide 1242. The second waveguide 1242 may be provided on the lower surface of the second substrate 121 and may be spaced apart laterally with respect to the grating coupler 122 and the first waveguide 1241. The second waveguide 1242 may include a different type of waveguide from the first waveguide 1241. As an example, the second waveguide 1242 may include a channel waveguide. The second waveguide 1242 may be formed by patterning a portion of the second substrate 121.

The photonic chip 120 may further include a modulator 126. The modulator 126 may be provided on the lower surface of the second substrate 121 and may be spaced apart laterally with respect to the grating coupler 122, the first waveguide 1241, and the second waveguide 1242. The modulator 126 may include a first doped region 126A, a second doped region 126B, a third doped region 126C, a fourth doped region 126D, a fifth doped region 126E, and a sixth doped region 126F. The second doped region 126B may be positioned between the first doped region 126A and the third doped region 126C. The third doped region 126C may be positioned between the second doped region 126B and the fourth doped region 126D. The fourth doped region 126D may be positioned between the third doped region 126C and the fifth doped region 126E. The fifth doped region 126E may be positioned between the fourth doped region 126D and the sixth doped region 126F. The first to third doped regions 126A, 126B, and 126C may include impurities of a first conductivity type. For example, the first to third doped regions 126A, 126B, and 126C may be doped with p-type impurities. The impurity concentrations of the first to third doped regions 126A, 126B, and 126C may be different from each other. The impurity concentration of the first conductivity type of the first doped region 126A may be greater than the impurity concentration of the first conductivity type of the second doped region 126B and the impurity concentration of the first conductivity type of the third doped region 126C. The impurity concentration of the first conductivity type of the second doped region 126B may be greater than the impurity concentration of the first conductivity type of the third doped region 126C. The fourth to sixth doped regions 126D, 126E, and 126F may include impurities of a second conductivity type. The impurities of the second conductivity type may be different from the impurities of the first conductivity type. For example, the fourth to sixth doped regions 126D, 126E, and 126F may be doped with n-type impurities. The impurity concentrations of the fourth to sixth doped regions 126D, 126E, and 126F may be different from each other. The impurity concentration of the second conductivity type of the sixth doped region 126F may be greater than the impurity concentration of the second conductivity type of the fourth doped region 126D and the impurity concentration of the second conductivity type of the fifth doped region 126E. The impurity concentration of the second conductivity type of the fifth doped region 126E may be greater than the impurity concentration of the second conductivity type of the fourth doped region 126D. Forming the modulator 126 may include patterning the second substrate 121 and performing a doping process.

The photonic chip 120 may further include a photodetector 127. The photodetector 127 may be provided on the lower surface of the second substrate 121. The photodetector 127 may be spaced apart laterally with respect to the grating coupler 122, the first waveguide 1241, the second waveguide 1242, and the modulator 126. The photodetector 127 may be formed by patterning a portion of the second substrate 121.

The photonic chip 120 may further include a first insulating layer 1211, second insulating layers 1212, and a third insulating layer 1213. The first to third insulating layers 1211, 1212, and 1213 may include a silicon-containing insulating material. The first to second insulating layers 1211 and 1212 may be transparent and transmit light.

The first insulating layer 1211 may be provided on the lower surface of the second substrate 121 (i.e., the first insulating layer 1211 may correspond to the lower surface of the second substrate 121). The first insulating layer 1211 may be provided between the second substrate 121 and the grating coupler 122, between the second substrate 121 and the first waveguide 1241, between the second substrate 121 and the second waveguide 1242, between the second substrate 121 and the modulator 126, and between the second substrate 121 and the photodetector 127. The first insulating layer 1211 may cover an upper surface of the grating coupler 122, an upper surface of the first waveguide 1241, an upper surface of the second waveguide 1242, an upper surface of the modulator 126, and an upper surface of the photodetector 127. The first insulating layer 1211 may include a silicon-containing insulating material.

The second insulating layer 1212 may be provided on a lower surface of the first insulating layer 1211 and may cover the lower surface of the grating coupler 122, a lower surface of the first waveguide 1241, a lower surface of the second waveguide 1242, a lower surface of the modulator 126, and a lower surface of the photodetector 127. The grating coupler 122, the first waveguide 1241, the second waveguide 1242, the modulator 126, and the photodetector 127 may be surrounded by the first insulating layer 1211 and the second insulating layer 1212. The second insulating layer 1212 may include a silicon-containing insulating material.

The photonic chip 120 may include a plurality of second insulating layers 1212. The plurality of second insulating layers 1212 may be stacked. The photonic chip 120 may include a single second insulating layer 1212.

The third insulating layer 1213 may be provided on lower surfaces of the second insulating layers 1212. The third insulating layer 1213 may include a lowermost insulating layer of the photonic chip 120. The third insulating layer 1213 may include a passivation layer. The third insulating layer 1213 may include a silicon-containing insulating material.

The photonic chip 120 may include first conductive lines 1281, second conductive lines 1282, and second lower pads 129. The first conductive lines 1281 may be positioned between the second insulating layers 1212. The first conductive lines 1281 may be electrically connected to at least one of the modulator 126 and the photodetector 127. The first conductive lines 1281 may be electrically isolated from each other. The first conductive lines 1281 may include the same metal material as the metal block pattern 123 and may have a thickness that is substantially the same as the metal block pattern 123. As an example, the first conductive lines 1281 may be formed through a single process with the metal block pattern 123.

The second conductive lines 1282 may be positioned between the lowermost second insulating layer 1212 and the third insulating layer 1213 and may be electrically connected to the first conductive lines 1281. The second conductive lines 1282 may include a conductive material, such as a metal.

The second lower pads 129 may be provided in the third insulating layer 1213 and may be electrically connected to the second conductive lines 1282. The second lower pads 129 may be laterally spaced apart from each other. The third insulating layer 1213 may cover sidewalls of the second lower pads 129. The lower surface of the photonic chip 120 may include lower surfaces of the second lower pads 129 and a lower surface of the third insulating layer 1213. The second lower pads 129 may include a conductive material, such as a metal. For example, the second lower pads 129 may include Cu.

The photonic chip 120 may be connected to the EIC chip 110 by direct bonding. Direct bonding of two chips may include direct bonding of conductive components of the two chips facing each other and direct bonding of insulating components of the two chips facing each other. The direct bonding of the insulating components may include forming a chemical bond between the insulating components. Hereinafter, for simplicity of explanation, a single second lower pad 129 and a single first upper pad 113 may be described.

For example, the second lower pad 129 may be disposed directly on the first upper pad 113 and may be directly bonded to the first upper pad 113. During the direct bonding process, the metal in the second lower pad 129 may be diffused into the first upper pad 113 and the metal in the first upper pad 113 may be diffused into the second lower pad 129. The second lower pad 129 may include the same metal as the first upper pad 113. Thus, the interface between the first upper pad 113 and the second lower pad 129 may not be distinguished. Thus, the second lower pad 129 may be rigidly bonded to the first upper pad 113. In FIGS. 1A and 1C, the interface between the first upper pad 113 and the second lower pad 129 may include a virtual interface. A sidewall of the first upper pad 113 may not be vertically aligned with a sidewall of the second lower pad 129.

The third insulating layer 1213 may directly contact the upper insulating layer 1121 and may be connected thereto by direct bonding. For example, a chemical bond may be provided between the third insulating layer 1213 and the upper insulating layer 1121. The chemical bond may include a covalent bond. Accordingly, the photonic chip 120 may be rigidly bonded to the EIC chip 110. The third insulating layer 1213 may include the same insulating material as the upper insulating layer 1121. The interface between the third insulating layer 1213 and the upper insulating layer 1121 may not be distinguished. In FIGS. 1A and 1C, the interface between the upper insulating layer 1121 and the third insulating layer 1213 may include a virtual interface.

Referring again to FIG. 1A, an upper surface of the second substrate 121 may include a first upper surface 121a1, a second upper surface 121a2, and a third upper surface 121a3 (e.g., the upper surface of the second substrate 121 may include three portions at varied heights and varied slants). The second upper surface 121a2 of the second substrate 121 may be adjacent to a first sidewall 120c of the photonic chip 120 in a plan view. Hereinafter, the first sidewall 120c of the photonic chip 120 also referred to as a photonic chip first sidewall. The second upper surface 121a2 of the second substrate 121 may be positioned between the first upper surface 121a1 of the second substrate 121 and the fiber optic device 150 in a plan view. The second upper surface 121a2 of the second substrate 121 may be substantially flat. For example, the second upper surface 121a2 of the second substrate 121 may be substantially parallel to the lower surface of the second substrate 121. The third upper surface 121a3 of the second substrate 121 may be provided at a lower level than the second upper surface 121a2 thereof. The third upper surface 121a3 of the second substrate 121 may be substantially flat. For example, the third upper surface 121a3 of the second substrate 121 may be substantially parallel to the lower surface of the second substrate 121. The third upper surface 121a3 of the second substrate 121 may be adjacent to a second sidewall of the photonic chip 120 in a plan view. The second sidewall of the photonic chip 120 may face the first sidewall 120c thereof. Hereinafter, the second sidewall of the photonic chip 120 also referred to as a photonic chip second sidewall. The first upper surface 121a1 of the second substrate 121 may be provided between the second upper surface 121a2 and the third upper surface 121a3. The first upper surface 121a1 of the second substrate 121 may include an inclined upper surface. For example, the first upper surface 121a1 of the second substrate 121 may be inclined with respect to the second upper surface 121a2 and the third upper surface 121a3 thereof. The angle between the first upper surface 121a1 and the third upper surface 121a3 of the second substrate 121 may include an obtuse angle. The first upper surface 121a1 of the second substrate 121 may not be parallel to the lower surface of the second substrate 121. The first upper surface 121a1 of the second substrate 121 may be connected to the second upper surface 121a2 and the third upper surface 121a3 thereof.

The reflective pattern 125 may be provided on the second substrate 121. For example, the reflective pattern 125 may be provided on the first upper surface 121a1 of the second substrate 121 to cover the first upper surface 121a1 thereof. The reflective pattern 125 may be horizontally spaced apart from the fiber optic device 150. For example, at least a portion of the reflective pattern 125 may be provided at substantially the same vertical level as the fiber optic device 150. The reflective pattern 125 may be vertically spaced apart from the grating coupler 122. At least a portion of the reflective pattern 125 may be provided on the first upper surface 121a1 of the second substrate 121. The reflective pattern 125 may further extend onto a portion of the second upper surface 121a2 of the second substrate 121. The reflective pattern 125 may further extend onto a portion of the first upper surface 121a1 of the second substrate 121. The reflective pattern 125 may include, for example, a metal. As an example, the reflective pattern 125 may include Ag, Au, Cu, Al, and/or alloys thereof.

The fiber optic device 150 may be provided on the first sidewall 120c of the photonic chip 120. The first sidewall 120c of the photonic chip 120 may include a first sidewall of the second substrate 121. That is, the fiber optic device 150 may be provided on the first sidewall of the second substrate 121. The fiber optic device 150 may include optical fibers. Light may be transmitted through the fiber optic device 150. The light may include an optical signal. The light may include a laser.

According to one or more embodiments, light incident through the fiber optic device 150 may be reflected by the reflective pattern 125 and may be incident on the grating coupler 122. The light may be transmitted to the modulator 126 and the photodetector 127 through the first waveguide 1241 and the second waveguide 1242 in FIG. 1C. The modulator 126 and the photodetector 127 may generate an electrical signal from the light. The electrical signal may be transmitted to the EIC chip 110 through the first and second conductive lines 1281 and 1282 and the second lower pad 129. The light may include, but is not limited to, a laser.

According to one or more embodiments, since the fiber optic device 150 is provided on the first sidewall 120c of the photonic chip 120 rather than on an upper surface of the photonic chip 120, a thickness T2 of the photonic chip 120 may be reduced. For example, the thickness T2 of the photonic chip 120 may be from about 300 μm to about 775 μm. Accordingly, the thickness of the optical engine device 10 may be reduced. The optical engine device 10 may be miniaturized.

The optical engine device 10 may further include at least one of a first connection assembly 161 and a second connection assembly 162. The first connection assembly 161 and the second connection assembly 162 may be provided between the first sidewall 120c of the photonic chip 120 and the fiber optic device 150. The second connection assembly 162 may be provided between the first connection assembly 161 and the fiber optic device 150. The first connection assembly 161 may include, but is not limited to, a receptacle. The second connection assembly 162 may include, but is not limited to, a ferrule. The fiber optic device 150 may be fixed onto the first sidewall 120c of the photonic chip 120 by the first connection assembly 161 and the second connection assembly 162.

The optical engine device 10 may further include the protective layer 180. The protective layer 180 may be provided on the second substrate 121 to cover the reflective pattern 125. The photonic chip 120 may further cover the second upper surface 121a2 and the first upper surface 121a1 of the second substrate 121. The protective layer 180 may protect the reflective pattern 125. The protective layer 180 may include a silicon-containing insulating material. For example, the protective layer 180 may include, but is not limited to, silicon oxide.

The first sidewall 120c of the photonic chip 120 may be vertically aligned with a first sidewall of the EIC chip 110 and a first sidewall of the redistribution substrate 130. The first sidewall of the EIC chip 110 may include a first sidewall of the upper insulating layer 1121, a first sidewall of the sealing layer 114, and a first sidewall of the lower insulating layer 1161. The first sidewall 120c of the photonic chip 120 may be vertically aligned with a first sidewall of the protective layer 180 but is not limited thereto.

The second sidewall of the photonic chip 120 may face the first sidewall 120c thereof. The second sidewall of photonic chip 120 may be vertically aligned with a second sidewall of the EIC chip 110 and a second sidewall of the redistribution substrate 130. The second sidewall of the EIC chip 110 may face the first sidewall of the EIC chip 110. The second sidewall of the redistribution substrate 130 may face the first sidewall of the redistribution substrate 130. The second sidewall of the photonic chip 120 may be vertically aligned with a second sidewall of the protective layer 180 but is not limited thereto.

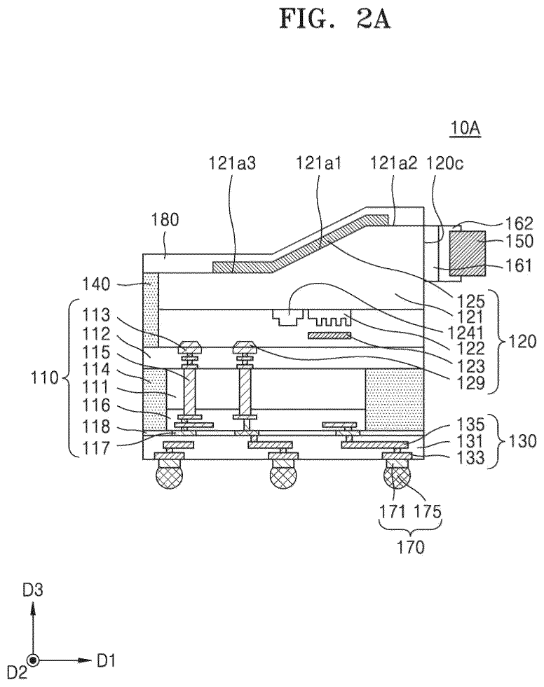

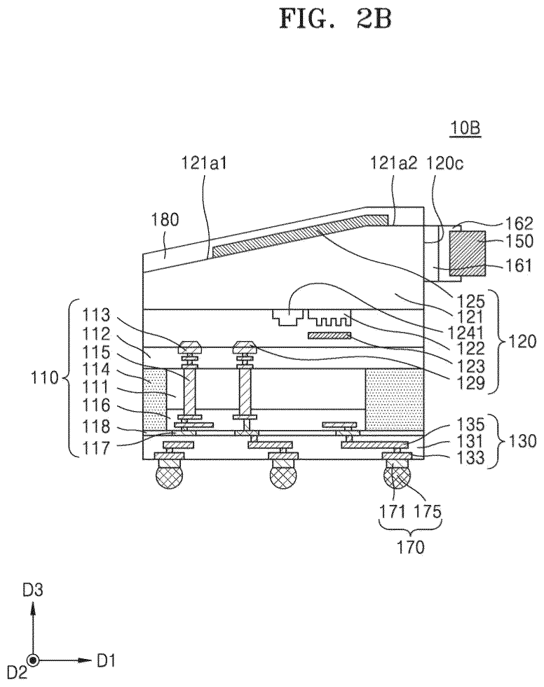

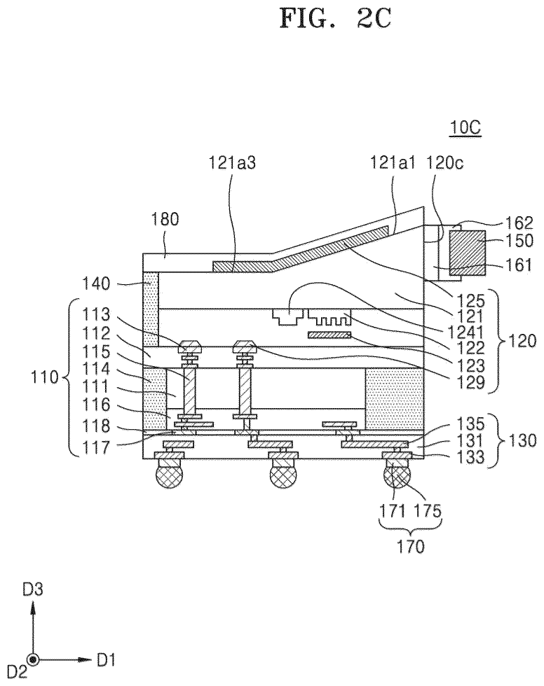

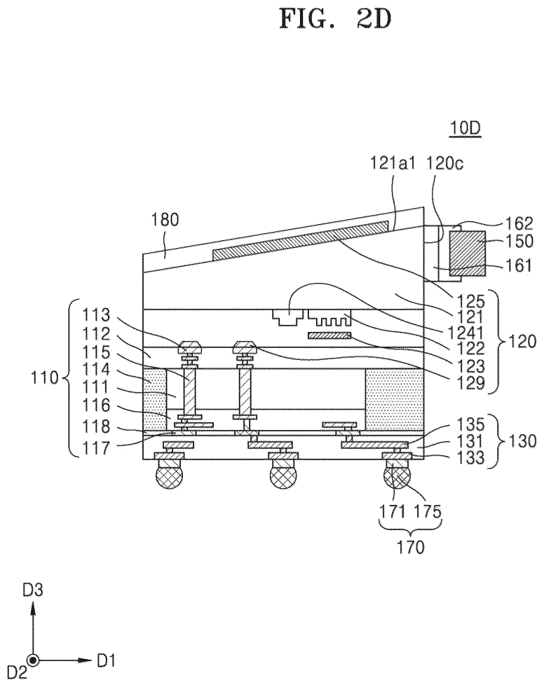

FIG. 2A is a cross-sectional view of an optical engine device according to one or more embodiments. Hereinafter, aspects that are substantially the same as aspects described above may be omitted.

Referring to FIG. 2A, an optical engine device 10A may include a molding pattern 140, in addition to a redistribution substrate 130, an EIC chip 110, a photonic chip 120, conductive bumps 170, a fiber optic device 150, and a protective layer 180.

The molding pattern 140 may be provided on the upper surface of the EIC chip 110. For example, the molding pattern 140 may be provided on the upper wiring layer 112. The molding pattern 140 may cover the second sidewall of the photonic chip 120. An outer wall of the molding pattern 140 may be vertically aligned with the second sidewall of the EIC chip 110 and the second sidewall of the redistribution substrate 130. The protective layer 180 may cover an upper surface of the molding pattern 140. The outer wall of the molding pattern 140 may be vertically aligned with the second sidewall of the protective layer 180. The molding pattern 140 may include an insulating polymer, such as an epoxy-based molding compound (EMC).

FIG. 2B is a cross-sectional view of an optical engine device according to one or more embodiments.

Referring to FIG. 2B, an optical engine device 10B may include a redistribution substrate 130, an EIC chip 110, a photonic chip 120, conductive bumps 170, a fiber optic device 150, and a protective layer 180.

A second substrate 121 may include a first upper surface 121a1 and a second upper surface 121a2. However, the second substrate 121 may not include the third upper surface 121a3 described with reference to FIG. 1A. The first upper surface 121a1 of the second substrate 121 may be adjacent to the second sidewall of the photonic chip 120. For example, the first upper surface 121a1 of the second substrate 121 may be between an edge of the second upper surface 121a2 to a top of a second sidewall of the second substrate 121. The second sidewall of the second substrate 121 may face a first sidewall of the first substrate 111.

FIG. 2C is a cross-sectional view of an optical engine device according to one or more embodiments.

Referring to FIG. 2C, an optical engine device 10C may include a redistribution substrate 130, an EIC chip 110, a photonic chip 120, conductive bumps 170, a fiber optic device 150, and a protective layer 180.

A second substrate 121 may include a first upper surface 121a1 and a third upper surface 121a3. However, the second substrate 121 may not include the second upper surface 121a2 described with reference to FIG. 1A. The first upper surface 121a1 of the second substrate 121 may be adjacent to the first sidewall 120c of the photonic chip 120. For example, the first upper surface 121a1 of the second substrate 121 may be between an edge of the third upper surface 121a3 to a top of the first sidewall of the second substrate 121.

FIG. 2D is a cross-sectional view of an optical engine device according to one or more embodiments.

Referring to FIG. 2D, an optical engine device 10D may include a redistribution substrate 130, an EIC chip 110, a photonic chip 120, conductive bumps 170, a fiber optic device 150, and a protective layer 180.

A second substrate 121 may include a first upper surface 121a1 but may not include the second upper surface 121a2 and the third upper surface 121a3 described with reference to FIG. 1A. That is, the upper surface of the second substrate 121 may be entirely inclined. The first upper surface 121a1 of the second substrate 121 may be between a top of a first sidewall of the second substrate 121 to a top of a second sidewall of the first substrate 111.

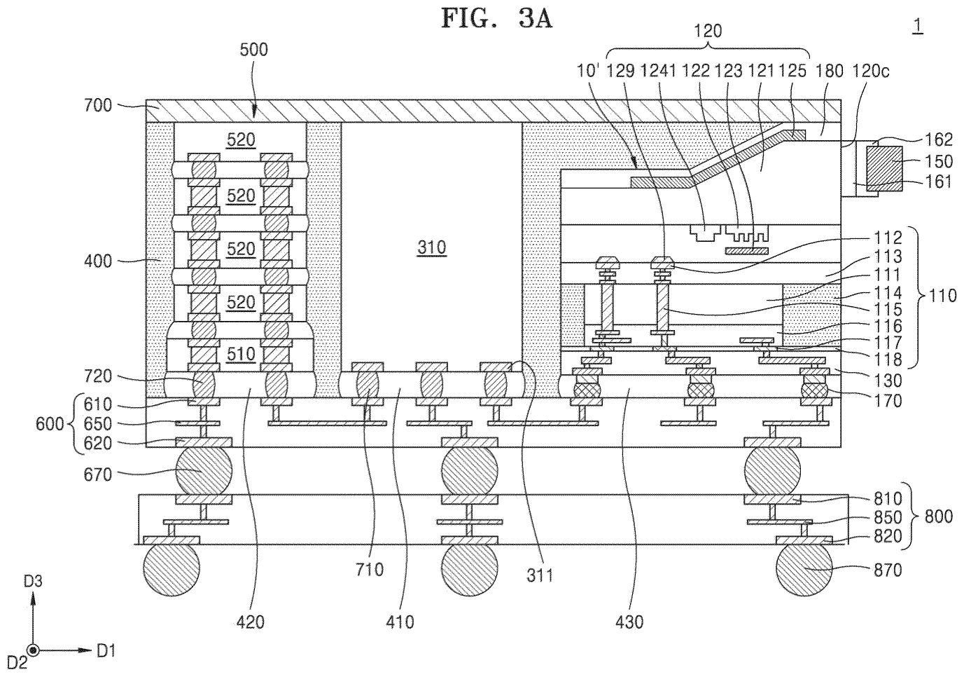

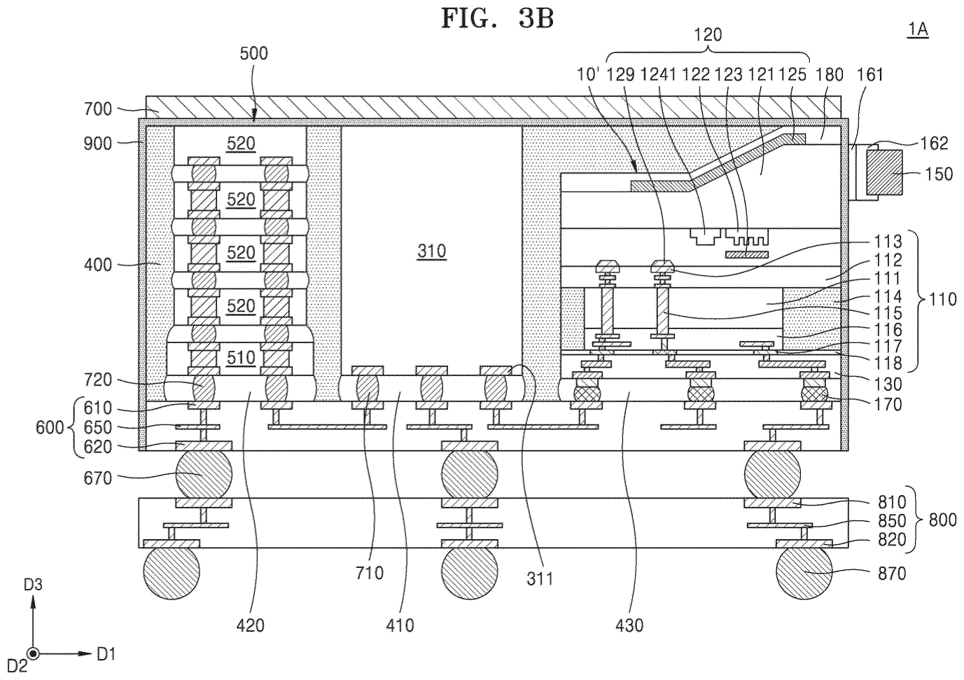

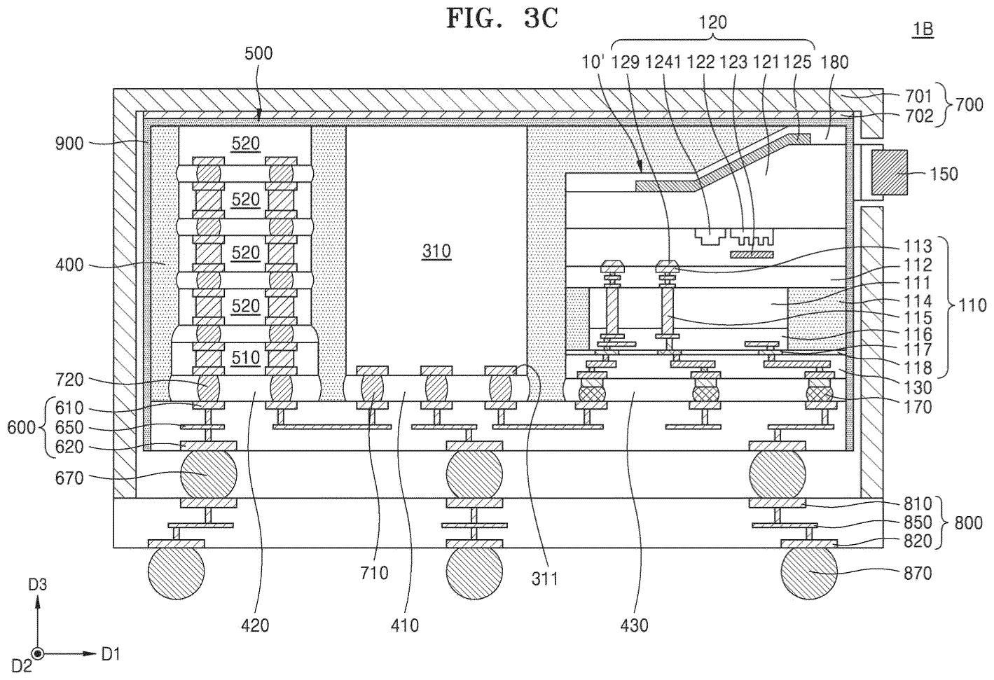

FIG. 3A is a cross-sectional view of a semiconductor package according to one or more embodiments. Hereinafter, descriptions of aspects that are substantially the same as aspects described above may be omitted.

Referring to FIG. 3A, a semiconductor package 1 may include an interposer substrate 600, a semiconductor chip 310, a memory device 500, an optical engine device 10′, a molding layer 400, and a heat dissipation structure 700.

The semiconductor package 1 may further include a package substrate 800 and solder ball terminals 870. The package substrate 800 may include metal wires 850, upper metal pads 810, and lower metal pads 820. The upper metal pads 810 may be provided on an upper surface of the package substrate 800. The metal wires 850 may be provided in the package substrate 800 and may be electrically connected to the upper metal pads 810. Being electrically connected to the package substrate 800 may refer to being electrically connected to the metal wires 850. The lower metal pads 820 may be provided on a lower surface of the package substrate 800. The lower metal pads 820 may be electrically connected to the upper metal pads 810 through the metal wires 850.

The solder ball terminals 870 may be disposed on the lower surface of the package substrate 800. For example, the solder ball terminals 870 may be respectively disposed on lower surfaces of the lower metal pads 820. The solder ball terminals 870 may be electrically connected to substrate wires 650 through the lower metal pads 820. The solder ball terminals 870 may include a solder material. The solder material may include, for example, Sn, Ag, zinc (Zn), and/or alloys thereof.

The interposer substrate 600 may include substrate wires 650, upper substrate pads 610, and lower substrate pads 620. The interposer substrate 600 may include a semiconductor substrate and a redistribution structure. The upper substrate pads 610 may be provided on an upper surface of the interposer substrate 600. The substrate wires 650 may be provided in the interposer substrate 600 and may be electrically connected to the upper substrate pads 610. Being electrically connected to the interposer substrate 600 may refer to being electrically connected to the substrate wires 650. The lower substrate pads 620 may be provided on a lower surface of the interposer substrate 600. The lower substrate pads 620 may be electrically connected to the upper substrate pads 610 through the substrate wires 650.

The interposer bumps 670 may be provided between the package substrate 800 and the interposer substrate 600. For example, the interposer bumps 670 may be provided between the lower substrate pads 620 and the upper metal pads 810 to connect to the lower substrate pads 620 and the upper metal pads 810. The interposer bumps 670 may include solder balls. The solder balls may include a solder material. The interposer bumps 670 further include conductive pillars, and the conductive pillars may be positioned between the lower substrate pads 620 and the solder balls. The conductive pillars may include solder balls and other metal. The pitch of the interposer bumps 670 may be less than the pitch of the solder ball terminals 870.

The semiconductor chip 310 may be disposed on the upper surface of the interposer substrate 600. The semiconductor chip 310 may include a logic chip. The logic chip may include an application specific integrated circuit (ASIC) chip. Alternatively, the logic chip may include an application processor (AP) chip, a central processing unit (CPU), or a graphics processing unit (GPU). The semiconductor chip 310 may include chip pads 311 on a lower surface thereof. The chip pads 311 may include a metal material, such as Al.

The semiconductor package 1 may include at least one of first bumps 710 and a first underfill film 410. The first bumps 710 may be positioned between the semiconductor chip 310 and the interposer substrate 600 to connect to the chip pads 311 and the corresponding upper substrate pads 610. The semiconductor chip 310 may be electrically connected to the interposer substrate 600 through the first bumps 710. The first bumps 710 may include first solder balls. The first solder balls may include a solder material. The first bumps 710 may further include first pillars. The first pillars may be provided between the chip pads 311 and the first solder balls and may include Cu. The pitch of the first bumps 710 may be less than the pitch of the interposer bumps 670. The first underfill film 410 may be provided between the semiconductor chip 310 and the interposer substrate 600 to cover sidewalls of the first bumps 710. The first underfill film 410 may include an insulating polymer.

The memory device 500 may be disposed on the upper surface of the interposer substrate 600 and may be laterally spaced apart from the semiconductor chip 310. The memory device 500 may include a memory package. The memory device 500 may include a lower semiconductor chip 510 and upper semiconductor chips 520. The lower semiconductor chip 510 may correspond to a lowermost semiconductor chip among the lower semiconductor chip 510 and the upper semiconductor chip 520 included in the memory device 500. The lower semiconductor chip 510 may include a different type of semiconductor chip than the semiconductor chip 310. For example, the lower semiconductor chip 510 may include a logic buffer chip. The upper semiconductor chips 520 may be stacked on the lower semiconductor chip 510. The upper semiconductor chips 520 may include a different type of semiconductor chips from the lower semiconductor chip 510 and the semiconductor chip 310. The upper semiconductor chips 520 may include memory chips. The upper semiconductor chips 520 may include high bandwidth memories (HBMs). For example, each of the upper semiconductor chips 520 may include dynamic random-access memory (DRAM).

The semiconductor package 1 may include at least one of second bumps 720 and a second underfill film 420. The second bumps 720 may be positioned between the memory device 500 and the interposer substrate 600 to connect to lower pads of the lower semiconductor chip 510 and the corresponding upper substrate pads 610. The memory device 500 may be electrically connected to the interposer substrate 600 through the second bumps 720. Accordingly, the memory device 500 may be electrically connected to the semiconductor chip 310 through the interposer substrate 600. The second bumps 720 may include second solder balls. The second solder balls may include a solder material. The second bumps 720 may further include second pillars. The second pillars may be provided between the memory device 500 and the second solder balls and may include Cu. The pitch of the second bumps 720 may be less than the pitch of the interposer bumps 670. The second underfill film 420 may be provided between the lower semiconductor chip 510 and the interposer substrate 600 to cover sidewalls of the second bumps 720. The second underfill film 420 may include an insulating polymer.

The optical engine device 10′ may be disposed on the upper surface of the interposer substrate 600. The optical engine device 10′ may be laterally spaced apart from the semiconductor chip 310 and the memory device 500. The semiconductor chip 310 may be positioned between the memory device 500 and the optical engine device 10′. The optical engine device 10′ may be the same as the optical engine device 10 described with reference to FIG. 1A. For example, the optical engine device 10 of FIG. 1A may be mounted on the interposer substrate 600 to form the optical engine device 10′. Alternatively, the optical engine device 10A of FIG. 2A, the optical engine device 10B of FIG. 2B, the optical engine device 10C of FIG. 2C, or the optical engine device 10D of FIG. 2D may be mounted on the interposer substrate 600 to form the optical engine device 10′. The optical engine device 10′ may include a redistribution substrate 130, conductive bumps 170, an EIC chip 110, a photonic chip 120, a protective layer 180, and a fiber optic device 150. The conductive bumps 170 may be connected to the corresponding first upper substrate pads 610. Accordingly, the optical engine device 10′ may be electrically connected to the interposer substrate 600 through the conductive bumps 170. The optical engine device 10′ may be electrically connected to the semiconductor chip 310 through the interposer substrate 600.

The semiconductor package 1 may further include a third underfill film 430. The third underfill film 430 may be provided between the interposer substrate 600 and the optical engine device 10′. For example, the third underfill film 430 may be provided between the interposer substrate 600 and the redistribution substrate 130 to cover sidewalls of the conductive bumps 170. The third underfill film 430 may include an insulating polymer.

The molding layer 400 may be provided on the upper surface of the interposer substrate 600 to cover the sidewall of the semiconductor chip 310 and the sidewall of the memory device 500. The molding layer 400 may cover a second sidewall of the optical engine device 10′ and may not cover a first sidewall of the optical engine device 10′ to expose the same. A first sidewall of the optical engine device 10′ may include the first sidewall 120c of the photonic chip 120, the first sidewall of the EIC chip 110, and the first sidewall of the redistribution substrate 130. The first sidewall of the optical engine device 10′ may be vertically aligned with a first sidewall of the interposer substrate 600. The first sidewall of the optical engine device 10′ may be vertically aligned with an outer wall of the third underfill film 430. The molding layer 400 may not cover an upper surface of the memory device 500, an upper surface of the semiconductor chip 310, and at least a portion of a upper surface of the optical engine device 10′ (i.e., these components may be exposed by the molding layer 400). The upper surface of the memory device 500 may include an upper surface of the uppermost second semiconductor chip 310. The upper surface of the optical engine device 10′ may include an upper surface of the protective layer 180. The molding layer 400 may further cover another portion of the upper surface of the protective layer 180 of the optical engine device 10′. For example, the molding layer 400 may include an insulating polymer, such as EMC. The molding layer 400 may include a material that is different from the first to third underfill films 410, 420, and 430.

The heat dissipation structure 700 may be disposed on at least a portion of the upper surface of the memory device 500, the upper surface of the semiconductor chip 310, and the upper surface of the optical engine device 10′. The heat dissipation structure 700 may further be provided on an upper surface of the molding layer 400. The heat dissipation structure 700 may include a cooling plate. The heat dissipation structure 700 may include a heat slug, a heat sink, and a thermal interface material (TIM) layer. Alternatively, the heat dissipation structure 700 may include a liquid cooling system. The heat dissipation structure 700 may include a material having a high thermal conductivity. The heat dissipation structure 700 may include, for example, a metal.

When the fiber optic device 150 is provided on the upper surface of the photonic chip 120, it may be difficult for the heat dissipation structure 700 to cover the upper surface of the optical engine device 10′ due to the fiber optic device 150. According to one or more embodiments, since the fiber optic device 150 is provided on the first sidewall 120c of the photonic chip 120, at least a portion of the upper surface of the optical engine device 10′ may be exposed. Accordingly, the heat dissipation structure 700 may be provided on the upper surface of the optical engine device 10′. The heat dissipation structure 700 may contact at least a portion of the upper surface of the optical engine device 10′. In operation of the optical engine device 10′, heat generated from the optical engine device 1′ may be rapidly released to the heat dissipation structure 700. Accordingly, the optical engine device 10′ may have improved thermal properties. In operation of the semiconductor package 1, the change in wavelength of the optical engine device 10′ may be reduced. The optical engine device 10′ may have improved operational reliability. The performance of the optical engine device 10′ may be improved.

FIG. 3B is a cross-sectional view of a semiconductor package according to one or more embodiments.

Referring to FIG. 3B, a semiconductor package 1A may include an anti-reflective layer 900, in addition to a package substrate 800, solder ball terminals 870, an interposer substrate 600, interposer bumps 670, a semiconductor chip 310, a memory device 500, an optical engine device 10′, a molding layer 400, and a heat dissipation structure 700.

The anti-reflective layer 900 may be provided on the upper surface of the memory device 500, the upper surface of the semiconductor chip 310, at least a portion of the upper surface of the optical engine device 10′, and the upper surface of the molding layer 400. The anti-reflective layer 900 may extend onto the first sidewall of the optical engine device 10′, the outer wall of the molding layer 400, and the outer walls of the interposer substrate 600. For example, the anti-reflective layer 900 may extend between the first sidewall of the optical engine device 10′ and the first connection assembly 161. The anti-reflective layer 900 may include an inorganic material, such as a silicon-containing material. The silicon-containing material may include, for example, silicon oxynitride.

FIG. 3C is a cross-sectional view of a semiconductor package according to one or more embodiments.

Referring to FIG. 3C, a semiconductor package 1B may include a package substrate 800, solder ball terminals 870, an interposer substrate 600, interposer bumps 670, a semiconductor chip 310, a memory device 500, an optical engine device 10′, a molding layer 400, and a heat dissipation structure 700.

The heat dissipation structure 700 may include a first heat dissipation structure 701 and a second heat dissipation structure 702. The first heat dissipation structure 701 may be provided on the upper surface of the memory device 500, the upper surface of the semiconductor chip 310, the upper surface of the optical engine device 10′, and the upper surface of the molding layer 400. The first heat dissipation structure 701 may further extend onto the outer wall of the molding layer 400 and the first sidewall of the optical engine device 10′. The heat dissipation structure 700 may further extend onto sidewalls of the interposer substrate 600. The first heat dissipation structure 701 may not cover the first connection assembly 161, the second connection assembly 162, and the fiber optic device 150. The first heat dissipation structure 701 may include a metal material. As an example, a heat sink may be used as the first heat dissipation structure 701. The first heat dissipation structure 701 may be electrically connected to at least one upper metal pad 810. In this case, a ground voltage may be applied to the first heat dissipation structure 701.

The second heat dissipation structure 702 may be positioned between the memory device 500 and the first heat dissipation structure 701, between the semiconductor chip 310 and the first heat dissipation structure 701, between the optical engine device 10′ and the first heat dissipation structure 701, and between the molding layer 400 and the first heat dissipation structure 701. The second heat dissipation structure 702 may include the TIM layer.

The semiconductor package 1B may further include an anti-reflective layer 900. The anti-reflective layer 900 may be positioned between the memory device 500 and the second heat dissipation structure 702, between the semiconductor chip 310 and the second heat dissipation structure 702, between the optical engine device 10′ and the second heat dissipation structure 702, and between the molding layer 400 and the second heat dissipation structure 702.

Alternatively, the semiconductor package 1B may not include the anti-reflective layer 900. In this case, the second heat dissipation structure 702 may cover the upper surface of the memory device 500, the upper surface of the semiconductor chip 310, the upper surface of the optical engine device 10′, and the upper surface of the molding layer 400.

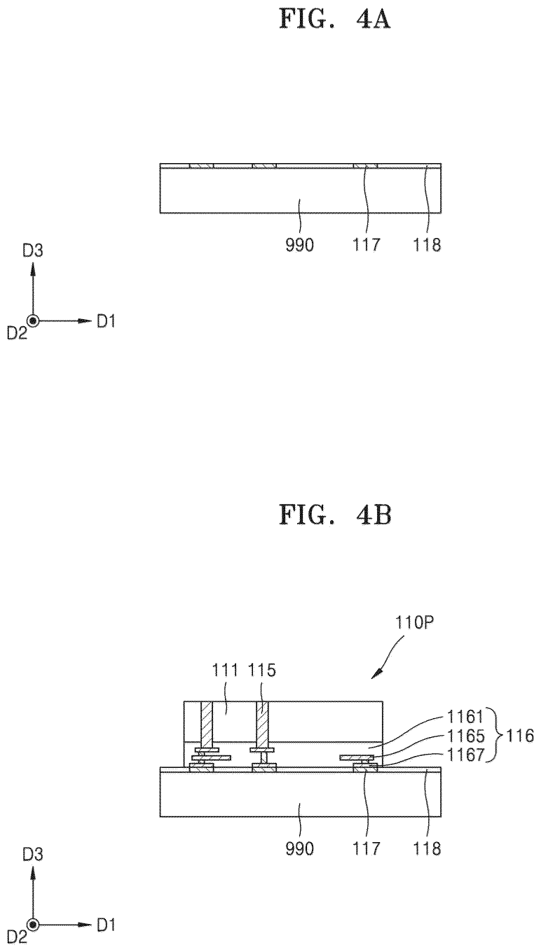

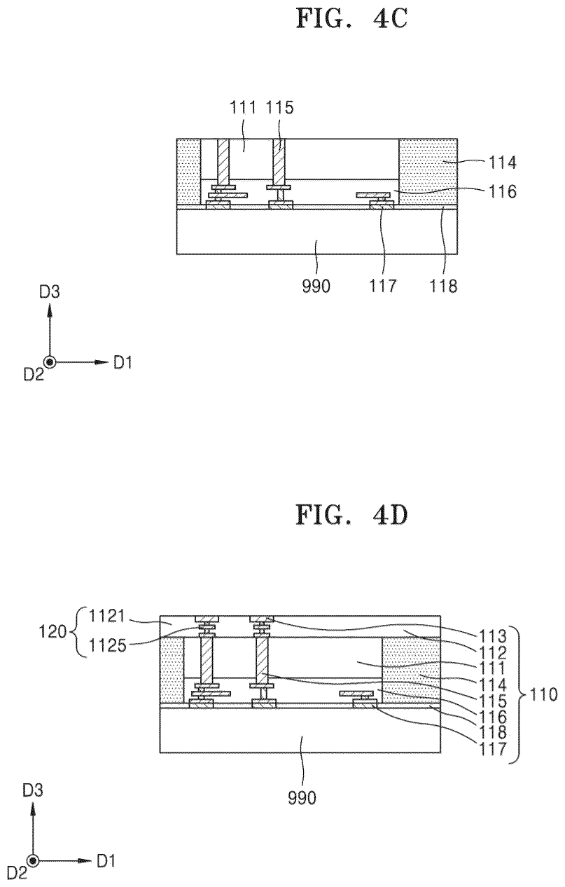

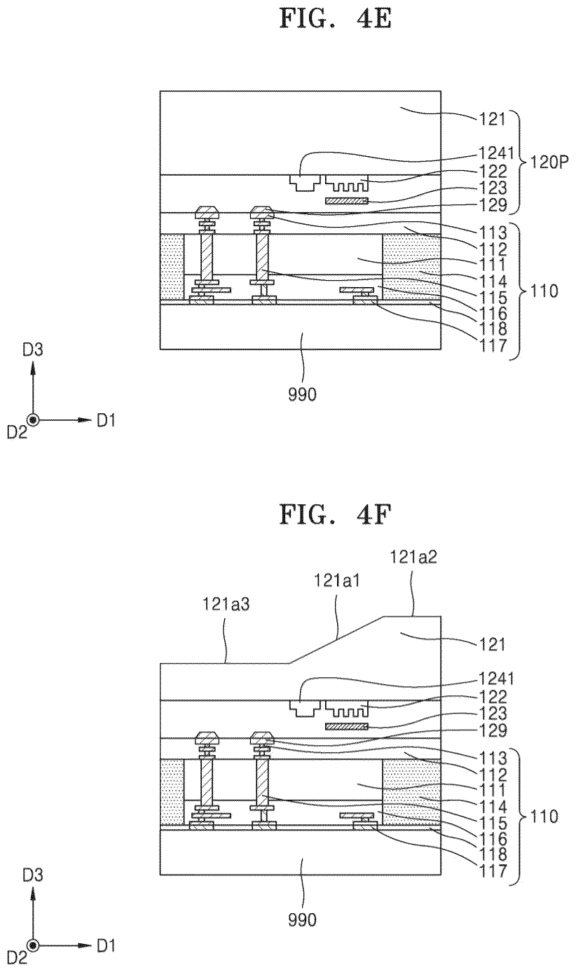

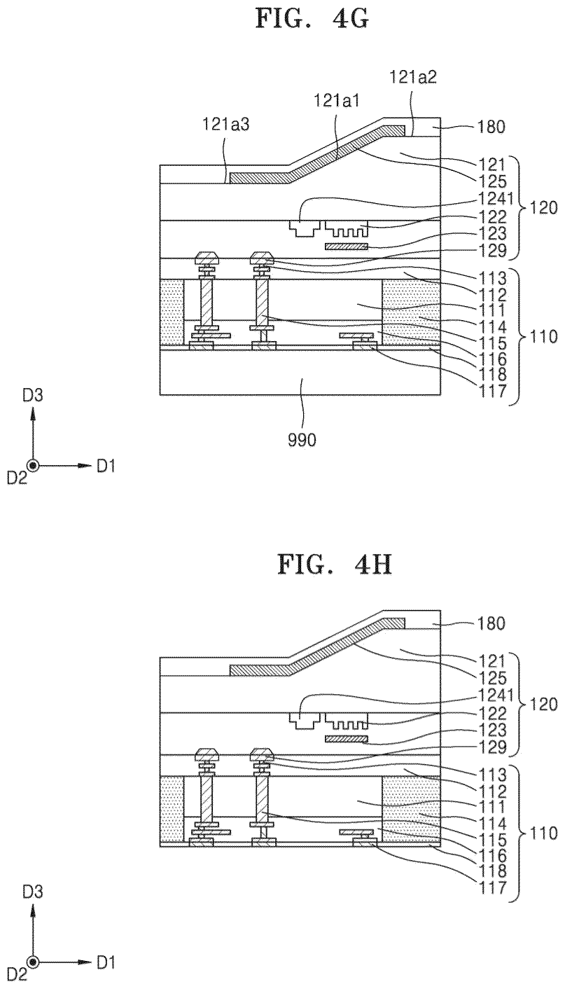

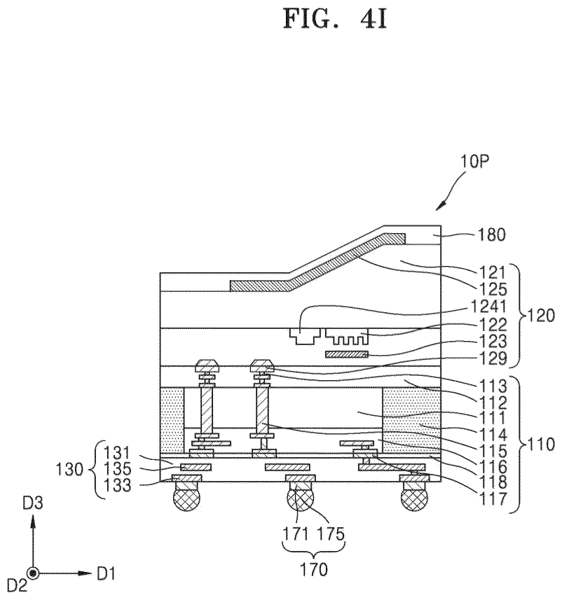

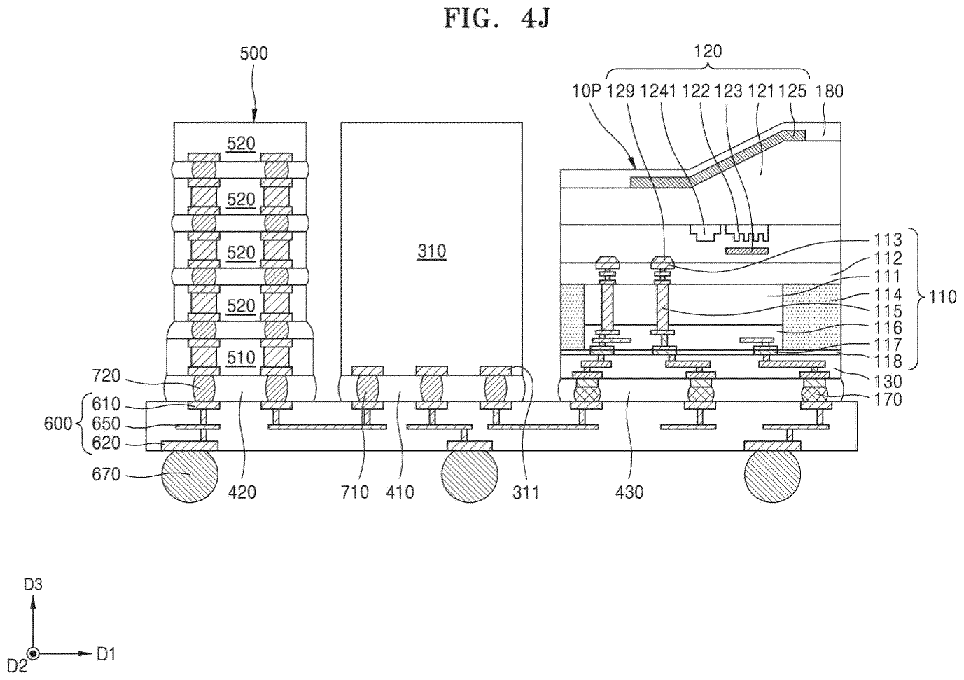

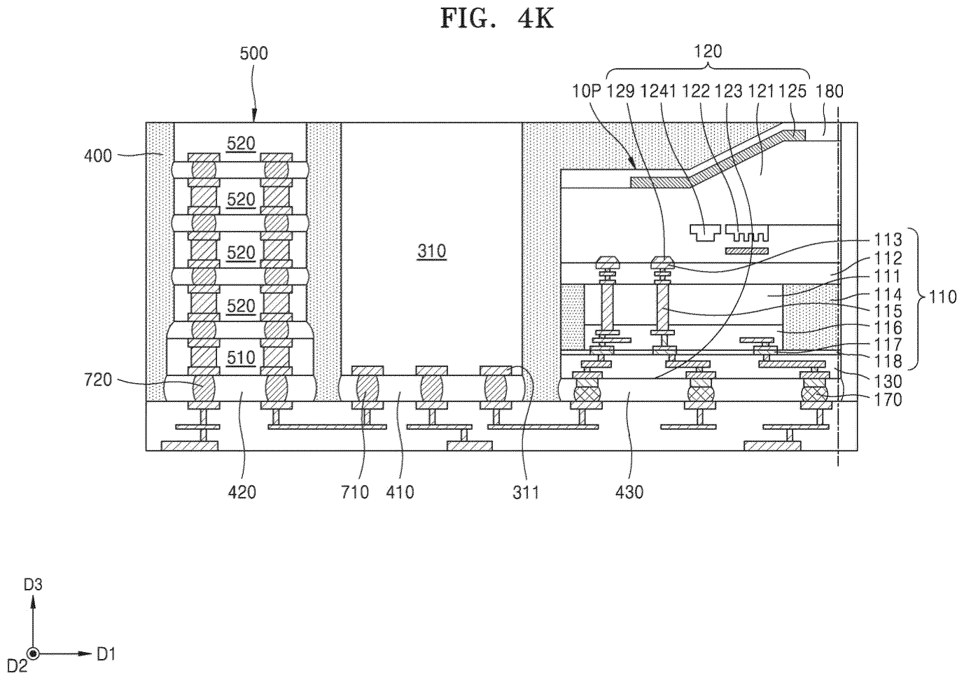

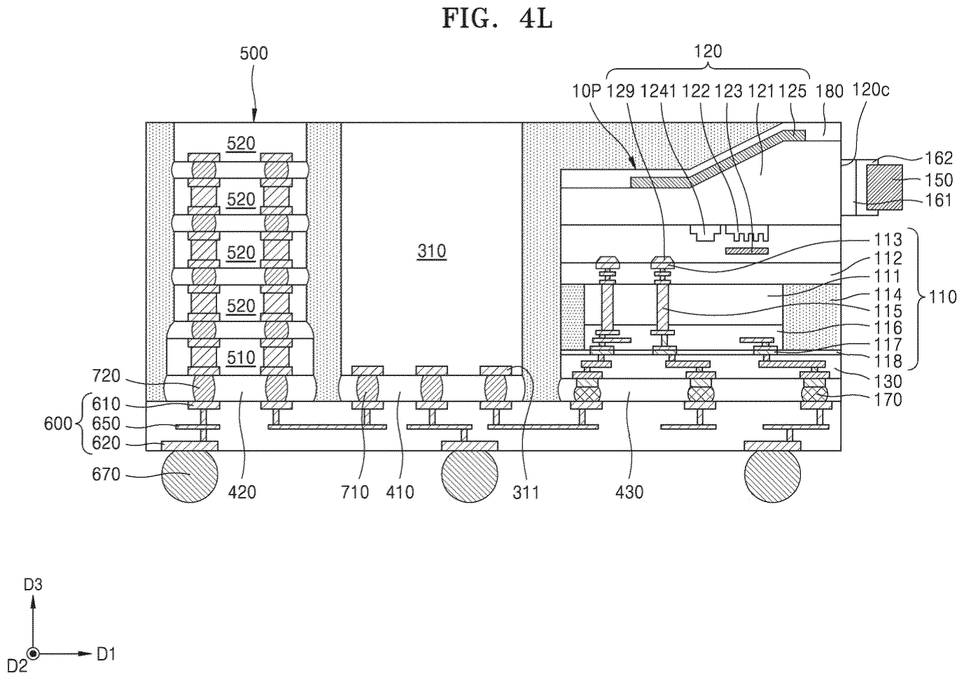

FIGS. 4A to 4L are diagrams illustrating a method of manufacturing an optical engine device and a semiconductor package including the same, according to one or more embodiments. Hereinafter, descriptions of aspects that are substantially the same as aspects described above may be omitted.

Referring to FIG. 4A, a temporary substrate 990 may be prepared. The temporary substrate 990 may include a wafer-level substrate. The temporary substrate 990 may include, but is not limited to, a silicon wafer. The first lower pads 117 and the lower insulating pattern 118 may be formed on the temporary substrate 990. The lower insulating pattern 118 may be formed by a deposition process, such as plasma enhanced chemical vapor deposition (PECVD). The first lower pads 117 and the lower insulating pattern 118 may be formed at the wafer level.

Referring to FIG. 4B, a preliminary electronic integrated circuit chip 110P may be prepared. The preliminary electronic integrated circuit chip 110P may include a first substrate 111, through vias 115, and a lower wiring layer 116. The lower wiring layer 116 may include a lower insulating layer 1161, lower conductive wires 1165, and bonding pads 1167. The preliminary electronic integrated circuit chip 110P may be bonded to the first lower pads 117 and the lower insulating pattern 118 by a hybrid bonding process. For example, the bonding pads 1167 may be bonded directly to the first lower pads 117, respectively. The lower insulating layer 1161 may be bonded directly to the lower insulating pattern 118. The hybrid bonding process may include applying heat and pressure to the preliminary electronic integrated circuit chip 110P.

Referring to FIG. 4C, a sealing layer 114 may be formed on the upper surface of the lower insulating pattern 118 to cover the sidewall of the lower wiring layer 116 and the sidewall of the first substrate 111. For example, the sealing layer 114 may be formed by a deposition process, such as PECVD. After forming the sealing layer 114, a chemical mechanical polishing process may be further performed on the sealing layer 114 and the first substrate 111. Upper surfaces of the through vias 115 may be exposed on the first substrate 111.

Referring to FIG. 4D, an upper wiring layer 112 may be formed on the first substrate 111 and on the sealing layer 114. The upper wiring layer 112 may include an upper insulating layer 1121 and upper conductive wires 1125. For example, the upper insulating layer 1121 may be formed by a deposition process, such as PECVD. The upper insulating layer 1121 and the upper conductive wires 1125 may be substantially the same as those described with reference to FIG. 1C. The first upper pads 113 may be formed on the upper wiring layer 112. The first upper pads 113 may be electrically connected to the upper conductive wires 1125.

Thereafter, a polishing process may be performed on the first upper pads 113 and the upper insulating layer 1121. The polishing process may include a chemical mechanical polishing process. As a result of the polishing process, the upper surfaces of the first upper pads 113 may be provided at substantially the same level as the upper surface of the upper insulating layer 1121. The EIC chip 110 may be manufactured by using the examples described above. The EIC chip 110 may include the first substrate 111, the lower wiring layer 116, the sealing layer 114, the first lower pads 117, the lower insulating pattern 118, the upper wiring layer 112, and the first upper pads 113.

Referring to FIG. 4E, a preliminary photonic chip 120P may be prepared. The preliminary photonic chip 120P may include a second substrate 121, second lower pads 129, a grating coupler 122, a metal block pattern 123, and a first waveguide 1241. The upper surface of the second substrate 121 may be substantially flat. The preliminary photonic chip 120P may further include the second waveguide 1242, the modulator 126, the photodetector 127, the first to third insulating layers 1211, 1212, and 1213, the first conductive lines 1281, and the second conductive lines 1282, described with reference to FIG. 1C.

The preliminary photonic chip 120P may be provided on the EIC chip 110. The preliminary photonic chip 120P may be bonded to the EIC chip 110 by a hybrid bonding process. For example, the second lower pads 129 may be bonded directly to the first upper pads 113. The hybrid bonding process may include applying heat and pressure to the EIC chip 110 and the preliminary photonic chip 120P.

Referring to FIG. 4F, an etching process using a hardmask may be performed on the second substrate 121 to form the first upper surface 121a1, the second upper surface 121a2, and the third upper surface 121a3 of the second substrate 121. A portion of the top of the second substrate 121 may be removed by the etching process. The first upper surface 121a1, the second upper surface 121a2, and the third upper surface 121a3 of the second substrate 121 may be substantially the same as those described with reference to FIG. 1A.

Referring to FIG. 4G, a reflective pattern 125 may be formed on the first upper surface 121a1 of the second substrate 121. The reflective pattern 125 may further extend onto a portion of the second upper surface 121a2 and a portion of the third upper surface 121a3 of the second substrate 121. Forming the reflective pattern 125 may include forming a metal layer by a deposition process and etching the metal layer. The reflective pattern 125 may expose another portion of the second upper surface 121a2 and another portion of the third upper surface 121a3 of the second substrate 121.

A protective layer 180 may be formed on the reflective pattern 125 and the second substrate 121 to cover the reflective pattern 125. The protective layer 180 may cover another portion of the second upper surface 121a2 of the second substrate 121 and another portion of the third upper surface 121a3 of the second substrate 121. The protective layer 180 may be formed by a deposition process, such as PECVD.

Referring to FIG. 4H, the temporary substrate 990 may be removed to expose the lower surfaces of the first lower pads 117 and the lower surface of the lower insulating pattern 118.

Referring to FIG. 4I, a redistribution substrate 130 may be formed on the lower surfaces of the first lower pads 117 and the lower surface of the lower insulating pattern 118. Forming the redistribution substrate 130 may include forming the substrate insulating layer 131 by a coating process, forming the redistribution patterns 135 by an electroplating process, and forming the redistribution pads 133. A method of forming the substrate insulating layer 131 and a method of forming the redistribution patterns 135 may vary.

The conductive bumps 170 may be formed on the lower surface of the redistribution substrate 130. For example, the conductive bumps 170 may be formed on the lower surfaces of the redistribution pads 133. Each of the conductive bumps 170 may include a pillar pattern 171 and a solder pattern 175.

A preliminary optical engine device 10P may be formed by using the examples described above. The preliminary optical engine device 10P may include the redistribution substrate 130, the conductive bumps 170, the EIC chip 110, the preliminary photonic chip 120P, and the protective layer 180.

Referring to FIG. 4J, an interposer substrate 600 may be prepared. The interposer substrate 600 may be substantially the same as that described with reference to FIG. 3A. The memory device 500 and the semiconductor chip 310 may be mounted on the upper surface of the interposer substrate 600. The memory device 500 may include a lower semiconductor chip 510 and upper semiconductor chips 520.

The first bumps 710 may be formed between the semiconductor chip 310 and the interposer substrate 600. The first underfill film 410 may be further formed between the semiconductor chip 310 and the interposer substrate 600 to cover the sidewalls of the first bumps 710.

The second bumps 720 may be formed between the lower semiconductor chip 510 and the interposer substrate 600. The second underfill film 420 may be further formed between the lower semiconductor chip 510 and the interposer substrate 600 to cover the sidewalls of the second bumps 720.

The preliminary optical engine device 10P may be provided on the interposer substrate 600. The preliminary optical engine device 10P may be disposed on the interposer substrate 600 such that the conductive bumps 170 of the preliminary optical engine device 10P are vertically aligned with the corresponding upper substrate pads 610. A reflow process of the conductive bumps 170 may be performed to connect the conductive bumps 170 to the upper substrate pads 610. Accordingly, the preliminary optical engine device 10P may be electrically connected to the interposer substrate 600.

The third underfill film 430 may be formed between the interposer substrate 600 and the preliminary optical engine device 10P. The third underfill film 430 may cover the sidewalls of the conductive bumps 170.

Referring to FIG. 4K, the molding layer 400 may be disposed on the interposer substrate 600 to cover sidewalls of the memory device 500, sidewalls of the semiconductor chip 310, and sidewalls of the preliminary optical engine device 10P. The preliminary optical engine device 10P may have a first sidewall and a second sidewall which face each other. The first sidewall and the second sidewall of the preliminary optical engine device 10P may be covered by the molding layer 400. The second sidewall of the preliminary optical engine device 10P may face the first sidewall thereof. The second sidewall of the preliminary optical engine device 10P may face the semiconductor chip 310.

A grinding process may be further performed on the molding layer 400 to expose the upper surface of the memory device 500, the upper surface of the semiconductor chip 310, and the upper surface of the preliminary optical engine device 10P. The upper surface of the preliminary optical device may include the upper surface of the protective layer 180.

Referring to FIGS. 4K and 4L, the molding layer 400 and the interposer substrate 600 may be sawed along a dash-dotted line. Accordingly, a portion of the molding layer 400 and a portion of the interposer substrate 600 may be removed. In the sawing process, a portion of the preliminary optical engine device 10P and a portion of the third underfill film 430 may be further removed but are not limited thereto. As a result of the sawing process, a first sidewall of the preliminary optical engine device 10P may be exposed. The first sidewall of the preliminary optical engine device 10P, the outer sidewall of the third underfill film 430, and the first sidewall of the interposer substrate 600 may be exposed in the sawing process. The first sidewall of the preliminary optical engine device 10P may be vertically aligned with the first sidewall of the interposer substrate 600 and the outer wall of the third underfill film 430.

Continuing with reference to FIG. 4L, at least one of the first connection assembly 161 and the second connection assembly 162 may be attached to the exposed first sidewall of the preliminary optical engine device 10P, particularly, the first sidewall 120c of the photonic chip 120.

For example, at least one of the first connection assembly 161 and the second connection assembly 162 may be attached to the first sidewall 120c of the photonic chip 120 via a transparent adhesive film (e.g., Polypropylene, and Polyethylene Terephthalate). For example, at least one of the first connection assembly 161 and the second connection assembly 162 may be attached to the first sidewall 120c of the photonic chip 120 via a physical coupling structure (e.g., a snap-fit structure).

The optical fiber device 150 may be attached to the preliminary optical engine device 10P via the first connection assembly 161 and/or the second connection assembly 162 to form the optical engine device 10. Interposer bumps 670 may be formed on the lower surface of the interposer substrate 600.

Referring again to FIG. 3A, the interposer substrate 600 may be mounted on the package substrate 800. For example, the interposer substrate 600 may be disposed on the package substrate 800 to vertically align the interposer bumps 670 with the upper substrate pads 610. A reflow process may be performed to bond the interposer bumps 670 to the upper substrate pads 610.

The heat dissipation structure 700 may be provided on the upper surface of the memory device 500, the upper surface of the semiconductor chip 310, the upper surface the optical engine device 10′, and the upper surface of the molding layer 400. The manufacturing of the semiconductor package 1 of FIG. 3A may be completed by using the examples described above.

Alternatively, the anti-reflective layer 900 may be further formed prior to providing the heat dissipation structure 700. The arrangement of the anti-reflective layer 900 is the same as that described with reference to FIG. 3B. The anti-reflective layer 900 may be formed by a coating process. Thereafter, the heat dissipation structure 700 may be provided on the upper surface of the anti-reflective layer 900. The manufacturing of the semiconductor package 1A of FIG. 3B may be completed by using the examples described above.

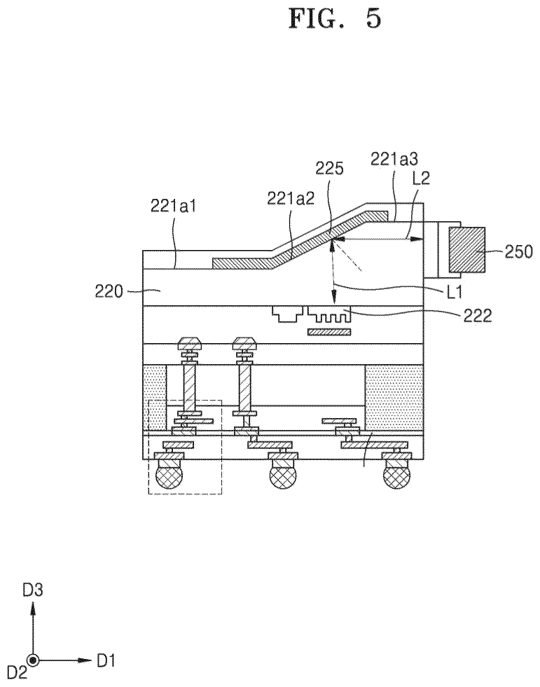

FIG. 5 is a cross-sectional view of an optical engine device, according to one more embodiments. Description of aspects the same as or similar to those described above may be omitted.

In FIG. 5, the optical engine device 20 may include a photonic chip 220 and a fiber optic device 250 provided on a side surface of the photonic chip 220. The upper surface of the photonic chip 220 may include three portions, a first portion 221a1, a second portion 221a2 that is inclined with respect to the first portion 221a1, and a third portion 221a3. The first portion 221a1 and the third portion 221a3 may be substantially parallel. A reflective pattern 225 may be provided on the upper surface of the photonic chip 220 and over the inclined portion 221a2. A grating coupler 222 may be provided in the photonic chip 220. The components in FIG. 5 may be implemented in a manner similar to the embodiments described above.

Due to the angle at which the portion 221a2 is inclined, the reflective pattern 225 allows light to properly interact with the grating coupler 222 (e.g., light L1) and the fiber optic device 250 (e.g., light L2) that is mounted on the sidewall of the photonic chip 220, as opposed to the fiber optic device being mounted on an upper surface of an optical engine device. Thus, the fiber optic device 250 may be functionally implemented on the sidewall of an optical engine device, allowing for the heat dissipation benefits and other benefits described above.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An optical engine device comprising:
an electronic integrated circuit (EIC) chip; and
a photonic chip on the EIC chip,
wherein the photonic chip comprises:
a first photonic chip sidewall;
a photonic chip substrate having an inclined upper surface; and
a reflective pattern on the inclined upper surface of the photonic chip substrate, and
wherein at least a portion of the reflective pattern is horizontally spaced apart from the first photonic chip sidewall.

2. The optical engine device of claim 1, wherein the photonic chip further comprises:
a grating coupler on a lower surface of the photonic chip substrate; and
a metal block pattern on a lower surface of the grating coupler and vertically spaced apart from the grating coupler, and
wherein a gap between the grating coupler and the metal block pattern is 0.5 μm to 5 μm.

3. The optical engine device of claim 1, further comprising a fiber optic device on the first photonic chip sidewall.

4. The optical engine device of claim 3, further comprising a redistribution substrate on a lower surface of the EIC chip, the redistribution substrate comprising an insulating layer and a redistribution pattern, and
wherein the first photonic chip sidewall is vertically aligned with one sidewall of the EIC chip and one sidewall of the redistribution substrate.

5. The optical engine device of claim 3, wherein the photonic chip comprises a second photonic chip sidewall horizontally opposite to the first photonic chip sidewall, and
wherein the optical engine device further comprises a molding pattern on the second photonic chip sidewall.

6. The optical engine device of claim 1, wherein an upper surface of the photonic chip comprises:
a first portion comprising the inclined upper surface;
a second portion between the first portion and the first photonic chip sidewall; and
a third portion at a lower level than the second portion,
wherein the first portion is between the second portion and the third portion, and
wherein the first portion is inclined with respect to the third portion.

7. The optical engine device of claim 1, wherein the photonic chip is hybrid bonded to the EIC chip.

8. The optical engine device of claim 1, wherein the EIC chip comprises:
an EIC substrate;
a through via in the EIC substrate;
a lower insulating layer on a lower surface of the EIC substrate;
a lower conductive wire in the lower insulating layer and connected to the through via;
a bonding pad on a lower surface of the lower insulating layer and connected to the lower conductive wire;
a first lower pad on a lower surface of the bonding pad; and
a lower insulating pattern covering a sidewall of the first lower pad,
wherein the bonding pad is directly bonded to the first lower pad, and
wherein the lower insulating layer is directly bonded to the lower insulating pattern.

9. The optical engine device of claim 8, wherein the EIC chip further comprises:
a sealing layer on an upper surface of the lower insulating pattern and covering a sidewall of the EIC substrate and a sidewall of the lower insulating layer; and
an upper wiring layer on an upper surface of the EIC substrate and an upper surface of the sealing layer, the upper wiring layer comprising an upper insulating layer and an upper conductive wire.

10. The optical engine device of claim 1, wherein a vertical thickness of the photonic chip is 300 μm to 775 μm.

11. A semiconductor package comprising:
an interposer substrate;
a semiconductor chip on an upper surface of the interposer substrate;
a memory device on the upper surface of the interposer substrate and horizontally spaced apart from the semiconductor chip; and
an optical engine device on the upper surface of the interposer substrate,
wherein the optical engine device comprises:
an electronic integrated circuit (EIC) chip comprising a through via;
a photonic chip on the EIC chip, the photonic chip comprising a first photonic chip sidewall; and
a fiber optic device on the first photonic chip sidewall,
wherein the photonic chip further comprises a reflective pattern horizontally spaced apart from at least a portion of the fiber optic device, and
wherein the first photonic chip sidewall is vertically aligned with a first EIC sidewall of the EIC chip and a first interposer sidewall of the interposer substrate.

12. The semiconductor package of claim 11, wherein the photonic chip further comprises a photonic chip substrate,
wherein the photonic chip substrate has an inclined upper surface, and
wherein the reflective pattern is on the inclined upper surface of the photonic chip substrate.

13. The semiconductor package of claim 11, further comprising a heat dissipation structure on an upper surface of the semiconductor chip, at least a portion of an upper surface of the photonic chip, and an upper surface of the memory device.

14. The semiconductor package of claim 11, further comprising a molding layer provided on the upper surface of the interposer substrate and covering a sidewall of the semiconductor chip, a sidewall of the memory device, and a second photonic chip sidewall of the photonic chip,
wherein the first photonic chip sidewall is not covered by the molding layer, and
wherein the second photonic chip sidewall is horizontally opposite to the first photonic chip sidewall.

15. The semiconductor package of claim 11, further comprising an anti-reflective layer covering an upper surface of the semiconductor chip, at least a portion of an upper surface of the photonic chip, and an upper surface of the memory device,
wherein the anti-reflective layer extends between the photonic chip and the fiber optic device.

16. An optical engine device comprising:
a redistribution substrate comprising a lower insulating layer and a redistribution pattern;
conductive bumps on a lower surface of the redistribution substrate;
an electronic integrated circuit (EIC) chip on an upper surface of the redistribution substrate; and
a photonic chip on the EIC chip,
wherein the EIC chip comprises:
an EIC substrate;
a through via in the EIC substrate;
a lower wiring layer on a lower surface of the EIC substrate, the lower wiring layer comprising a lower insulating layer and a lower conductive wire; and
an upper wiring layer on an upper surface of the EIC substrate, the upper wiring layer comprising an upper insulating layer and an upper conductive wire, and
wherein the photonic chip comprises:
a first photonic chip sidewall;
a photonic chip substrate having an inclined upper surface;
insulating layers on a lower surface of the photonic chip substrate;
a bonding coupler between the insulating layers;
a metal block pattern vertically spaced apart from a lower surface of the bonding coupler; and
a reflective pattern on the inclined upper surface of the photonic chip substrate and horizontally spaced apart from the first photonic chip sidewall.

17. The optical engine device of claim 16, wherein the EIC chip further comprises a sealing layer on the redistribution substrate and covering a sidewall of the EIC substrate and a sidewall of the lower wiring layer, and
wherein the upper wiring layer is on an upper surface of the sealing layer.

18. The optical engine device of claim 17, further comprising a fiber optic device on the first photonic chip sidewall.

19. The optical engine device of claim 18, wherein the first photonic chip sidewall is vertically aligned with one sidewall of the upper insulating layer and one sidewall of the sealing layer.

20. The optical engine device of claim 16, wherein the EIC chip further comprises a first upper pad on an upper surface of the upper wiring layer and connected to the through via,
wherein the photonic chip further comprises a lower pad on the lower surface of the photonic chip, and
wherein the lower pad is directly bonded to the first upper pad.
